(19) United States
(12) Patent Application Publication
(10) Pub. No.: US 2009/0211638 A1
(43) Pub. Date: Aug. 27, 2009

(54) MULTIPLE-DYES SENSITIZED SOLAR CELLS AND A METHOD FOR PREPARING THE SAME

(76) Inventors: Nam-Gyu PARK, Seoul (KR); Kyung-Kon KIM, Seoul (KR); Kyung-Tae LEE, Seoul (KR)

Correspondence Address: MCNEELY BODENDORF LLP, P.O. BOX 34175, WASHINGTON, DC, 20043, US

(21) Appl. No.: 12/393,055

(22) Filed: Feb. 26, 2009

(30) Foreign Application Priority Data
Feb. 26, 2008 (KR) 10-2008-0017071

(51) Int. Cl. H01L 31/00; H01L 31/0352

(52) U.S. Cl. 136/262; 136/252; 438/85; 977/779; 257/E31.032; 438/73

(57) ABSTRACT

Provided are a dye-sensitized solar cell and a method for preparing the same. A dye-sensitized solar cell may include a photoelectrode comprising at least two kinds of dye layers having different wavelengths on a transparent conductive substrate, and a counter electrode comprising a platinum (Pt) layer on a transparent conductive substrate. The counter electrode may be arranged opposite to the photoelectrode and an electrolyte may be filled between the photoelectrode and the counter electrode.

### CROSS-REFERENCE TO RELATED APPLICATION(S)

This application claims the benefit under 35 U.S.C. §119(a) of a Korean Patent Application No. 10-2008-0017071, filed on Feb. 26, 2008 in the Korean Intellectual Property Office, the entire disclosure of which is hereby incorporated by reference.

### TECHNICAL FIELD

The following description relates to a dye-sensitized solar cell and a method for preparing the same, more particularly, to a dye-sensitized solar cell of series structure having multiple dye layers which are formed by a removable polymer identical to or different from each other, and a method for preparing the same.

### BACKGROUND

FIG. 1A shows a general structure of a dye sensitized solar cell (or a dye-sensitized photovoltaic cell) as represented by a photoelectrochemical solar cell announced by Gratzel et al., Switzerland, in 1991. A dye-sensitized solar cell or dye-sensitized solar cells are generally comprised of a transparent conductive substrate 10, a photoabsorption layer 30, a counter electrode 70, and an electrolyte 40. The photoabsorption layer may be formed by absorbing photosensitive dyes 31a to metal oxide nanoparticles 32 having wide band gap energy, and the counter electrode may be formed by coating platinum (Pt) 60 on a transparent conductive substrate 10.

In dye-sensitized solar cells, photosensitive dyes absorb incident solar rays and turn to an excited state, thereby transmitting electrons to the conduction band of the metal oxide. The transmitted electrons move to an electrode and flow to an external circuit to transfer the electrical energy, and turn to a lower energy state according to the energy transfer and moves to the counter electrode. Then, the photosensitive dyes are provided with electrons from the electrolyte solution 40 as much as the dyes transfer to the metal oxide, and turn to the original state, wherein the electrolyte receives electrons from the counter electrode and transfer them to photosensitive dyes via an oxidation-reduction process.

In order to absorb light in a broad wavelength range, a single dye having a wide absorption wavelength range may be developed, or two or more nanoparticle layers may be deposited to absorb dyes having different absorption wavelengths. In the latter case, light in a broad wavelength range can be absorbed as shown in FIG. 3, and thus it is possible to control an absorption wavelength range of dye-sensitized solar cells using already developed dyes having various absorption wavelength ranges, thereby improving the efficiency.

However, in order to enable the metal oxide nanoparticle layer to transfer electrons, high temperature sintering process is typically conducted. In addition, because dyes are easily degraded at high temperature, additional sintering of metal oxide nanoparticles may not be conducted after conducting the dye absorption once. For this reason, conventional dye-sensitized solar cells have used one kind of dye or simply mixed two or more kinds of dyes. In addition, as shown in FIG. 1B, two or more individual cells respectively comprising dyes absorbing light of different wavelength ranges were stacked in order to improve the efficiency. However, such a method is problematic in that two conductive substrates are placed between the photoabsorption layer, thus lowering the transparency which is the advantage of dye-sensitized solar cells, and the amount of light reaching the rear photoabsorption layer is reduced. Moreover, since two individual cells are stacked, the efficiency is less compared to a single cell.

### SUMMARY

According to an aspect, there is provided a transparent dye-sensitized solar cell which has a multiple dyes layered structure in a metal oxide nanoparticle layer in a single cell.

According to another aspect, there is provided a dye-sensitized solar cell including a photoelectrode comprising at least two kinds of dye layers having different wavelengths on a transparent conductive substrate, a counter electrode comprising a platinum (Pt) layer on a transparent conductive substrate, arranged opposite to the photoelectrode, and an electrolyte filled between the photoelectrode and the counter electrode.

The dye layer may include identical or different kinds of dyes.

The dye layer may include dyes selected from the group consisting of metal complex, inorganic dye and organic dye.

The dye layer may include a metal oxide nanoparticle layer to which dyes are absorbed.

The metal oxide nanoparticle layer may include at least one selected from the group consisting of titanium oxide, zirconium oxide, strontium oxide, zinc oxide, indium oxide, lanthanum oxide, vanadium oxide, molybdenum oxide, tungsten oxide, tin oxide, niobium oxide, magnesium oxide, aluminum oxide, yttrium oxide, scandium oxide, samarium oxide, gallium oxide, and strontium titanium oxide.

The dye-sensitized solar cell may further include at least two kinds of dye layers having different wavelengths on the platinum (Pt) layer of the counter electrode.

According to still another aspect, there is provided a method for preparing a dye-sensitized solar cell, the method including forming a metal oxide nanoparticle layer on a transparent conductive substrate having a blocking layer formed thereon, and absorbing a first dye into the metal oxide nanoparticle layer, forming a polymer material in the metal oxide nanoparticle layer to which the first dye is absorbed, desorbing dyes on top of the substrate having polymer material formed thereon using a basic desorption solution, reabsorbing a second dye on the desorbed part, removing the polymer material after absorption of the second dye to prepare a photoelectrode having at least two kinds of dye layers having different wavelengths, forming a platinum (Pt) layer on a transparent conductive substrate to prepare a counter electrode, and oppositely arranging the photoelectrode and the counter electrode and filling an electrolyte therebetween.

The method may further include applying a nanoparticle paste on the platinum (Pt) layer of the counter electrode and heating it to form a metal oxide nanoparticle layer, absorbing the first dye into the metal oxide nanoparticle layer, forming the polymer material in the metal oxide nanoparticle layer to which the first dye is absorbed, desorbing dyes on top of the substrate having the polymer material formed thereon using a basic desorption solution, reabsorbing the second dye in the desorbed part, and removing the polymer material after absorption of the second dye to prepare a counter electrode comprising at least two kinds of dye layers having different wavelengths.

The method may further include forming multiple dye layers by one or more times conducting, after removing the polymer material, reforming polymer material in the second dye layer, desorbing the second dye, reabsorbing an additional dye having a wavelength different from those of first and second dyes, and removing the polymer material, or, after reabsorbing the second dye, desorbing the second dye, reabsorbing the additional dye having the wavelength different from those of the first and second dyes, and removing the polymer material.

The polymer material may be formed by dispersing an oligomer material in the oxide particle layer, and forming the polymer material in the particle layer by polymerization.

The blocking layer may be formed by spin coating metal oxide precursor or metal oxide nanoparticle solution on a transparent conductive substrate, and the metal oxide nanoparticle layer is formed by applying metal oxide paste on the blocking layer and heating.

The heating may be conducted at a temperature of from 400 to 550° C. for 10 to 120 minutes.

Other features and aspects will be apparent from the following detailed description, the drawings, and the claims

### BRIEF DESCRIPTION OF THE DRAWINGS

FIG. 1A is a diagram illustrating a structure of an organic dye-sensitized solar cell.

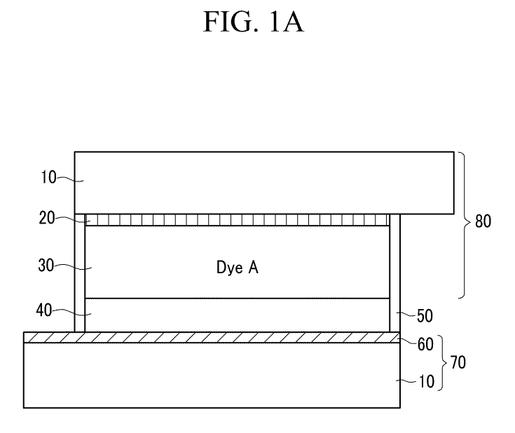

FIG. 1B is a diagram illustrating an organic dye-sensitized solar cell of series structure.

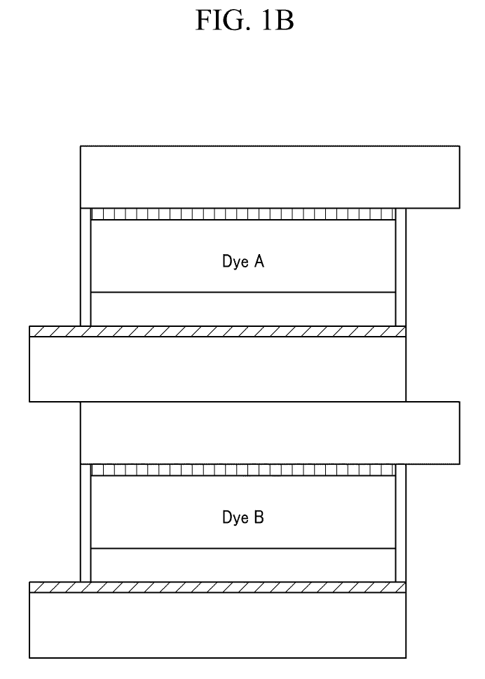

FIG. 2A is a diagram illustrating a structure of a multiple dyes sensitized solar cell according to an exemplary embodiment.

FIG. 2B is a diagram illustrating a structure of a multiple dyes sensitized solar cell applying a counter electrode according to another exemplary embodiment.

FIG. 2C is a diagram illustrating a manufacturing process of a multiple dyes sensitized solar cell according to an exemplary embodiment.

FIG. 3 shows graphs comparing an absorption range of a conventional single dye structure and a broad absorption range of a multiple dyes layered structure according to an exemplary embodiment.

FIG. 4 is a diagram illustrating the result of a ruthenium EPMA element analysis, which shows the distribution of dye absorption when a styrene oligomer is spin coated in TiO₂ nanoparticle layer and polymerized, and immersed in ruthenium based dye solution for 50 minutes.

FIG. 5 is a graph illustrating the result of measuring current-voltage under 1.5 AM light irradiation condition of an example 2 and a comparative example 1.

FIG. 6 is a graph illustrating the result of measuring Incident Photon to current Conversion Efficiency (IPCE) of the example 2 and the comparative example 1.

Throughout the drawings and the detailed description, unless otherwise described, the same drawing reference numerals will be understood to refer to the same elements, features, and structures. The relative size and depiction of these elements may be exaggerated for clarity, illustration, and convenience.

### EXPLANATION OF REFERENCE NUMERALS OF THE DRAWINGS

| | |
|---|---|
| 10: transparent conductive substrate | |
| 20: blocking layer | |
| 30: Photoabsorption layer | |
| 31a: first dye | 31b: second dye |
| 32: metal oxide nanoparticle | |
| 40: oxidation/reduction electrolyte | |
| 50: binder resin | 60: Platinum (Pt) layer |
| 70: counter electrode (or rear electrode) | |
| 80: photoelectrode (or front electrode) | |
| 90: polymer | |

### DETAILED DESCRIPTION

The following detailed description is provided to assist the reader in gaining a comprehensive understanding of the methods, apparatuses, and/or systems described herein. Accordingly, various changes, modifications, and equivalents of the systems, apparatuses and/or methods described herein will be suggested to those of ordinary skill in the art. Also, descriptions of well-known functions and constructions may be omitted for increased clarity and conciseness.

The following description relates to multiple dyes sensitized solar cells and a method for preparing the same. According to an exemplary embodiment, a metal oxide nanoparticle layer is formed on a conductive substrate and a first dye capable of absorbing light in a specific wavelength range is absorbed thereto, and then, a polymer material is formed in the metal oxide nanoparticle layer to reduce the pore size of the nanoparticle layer, and surface dyes are desorbed and a second dye capable of absorbing light in another wavelength range is reabsorbed.

Dye sensitized solar cells and its preparation method according to an exemplary embodiment will be further explained with reference to the attached drawings.

Dye sensitized solar cells according to an exemplary embodiment comprise a photoelectrode comprising at least two kinds of dye layers having different wavelengths on a transparent conductive substrate, a counter electrode comprising a Platinum (Pt) layer on a transparent conductive substrate, arranged opposite to the photoelectrode, and an electrolyte filled between the photoelectrode and the counter electrode. In addition, the dye sensitized solar cells may further comprise at least two kinds of dye layers having different wavelengths on the Platinum (Pt) layer of the counter electrode. The dye layers may comprise a metal oxide nanoparticle layer to which identical or different two or more kinds of dyes are absorbed.

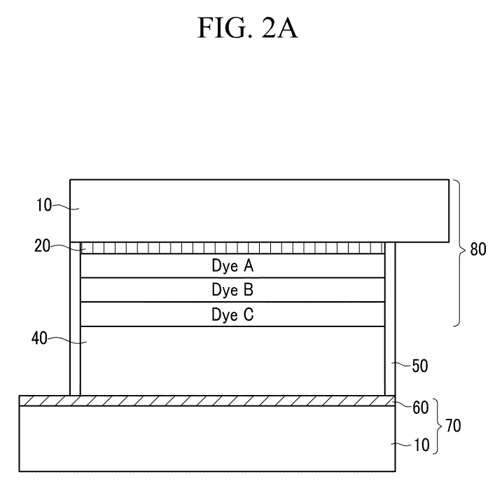

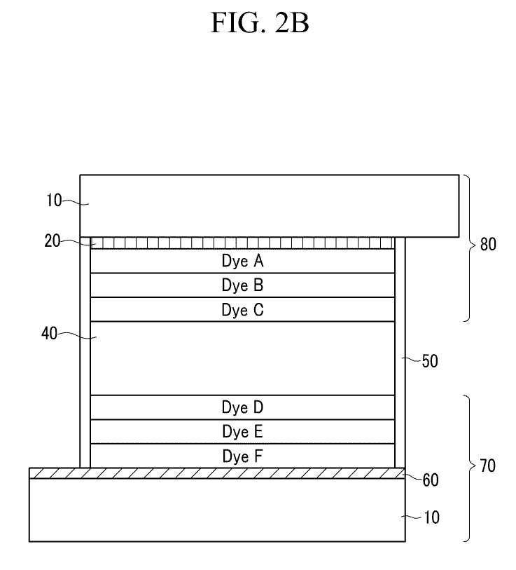

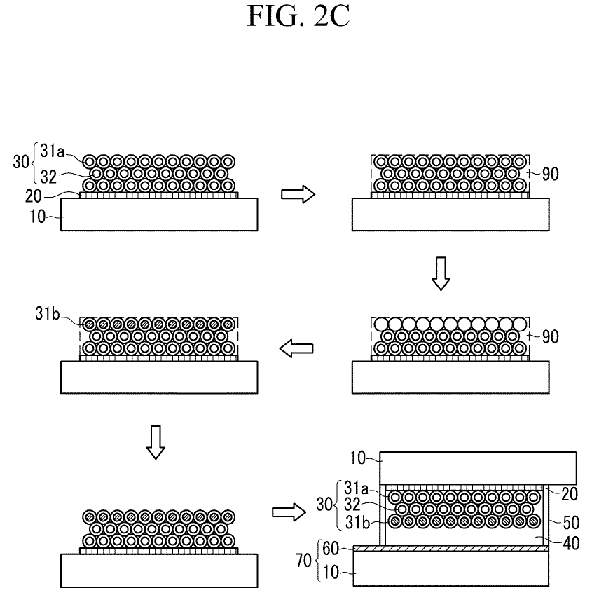

FIG. 2A shows a structure of a multiple dyes sensitized solar cell according to an exemplary embodiment. As shown in FIG. 2A, a dye sensitized solar cell may comprise a blocking layer 20 on a transparent substrate 10, a photoelectrode 80 comprising a metal oxide layer having a dye layer A, a dye layer B and a dye layer C thereon, a counter electrode 70 comprising a Platinum (Pt) layer 60 on a transparent substrate 10, arranged opposite to the photoelectrode 80, an electrolyte 40 filled between the photoelectrode and the counter electrode, and a binding resin 50.

FIG. 2B shows a structure of a multiple dyes sensitized solar cell applying a counter electrode according to another exemplary embodiment. As shown in FIG. 2B, a dye sensitized solar cell may comprise a blocking layer 20 on a transparent substrate 10, a photoelectrode 80 comprising a metal oxide layer having a dye layer A, a dye layer B and a dye layer C thereon, a counter electrode 70 which is arranged opposite to the photoelectrode 80 and comprises a Platinum (Pt) layer 60 on a transparent substrate 10 and a metal oxide layer having a dye layer D, a dye layer E and a dye layer F on the Platinum (Pt) layer, an electrolyte 40 filled between the photoelectrode and the counter electrode, and a binder resin 50.

The dye layers A to F, which are photo absorption layers, may use identical or different kinds of dyes and their wavelengths may be identical or different. Although not shown in FIGS. 2A and 2B, the dye layer comprises a metal oxide nanoparticle layer.

A method for preparing the dye sensitized solar cell having the above structure will be explained below.

FIG. 2C shows a manufacturing process of a multiple dyes sensitized solar cell according to an exemplary embodiment. As shown in FIG. 2C: (a) metal oxide precursors or nanoparticles are applied on a transparent conductive substrate 10 as a blocking layer 20, and then heated; (b) on the blocking layer, a metal oxide nanoparticle paste comprising the metal oxide nanoparticles 32 is applied and heated; (c) a first dye 31a is absorbed to the sintered particle layer; (d) an oligomer solution is applied and polymerized to form a polymer material 90 in the metal oxide particle layer; then, (e) dyes only on top of the metal oxide nanoparticle layer are desorbed using a basic solution; subsequently, (f) different kind of second dye material 31b is absorbed only on the desorbed part, which is due to delay in absorption speed and penetration depth of dye solution due to polymer; and finally, (h) the polymer layer is immersed in an organic solvent to remove the polymer thereby providing a photoelectrode which comprises the photoabsorption layer 30 comprising the metal oxide nanoparticles consisting of dual dyes. In addition, the above process may be repeated to form a structure comprising triple or more multiple dye layers (FIG. 2A, 2B).

A Platinum (Pt) layer 60 may be formed on a transparent substrate 10 to prepare a counter electrode 70, and the electrolyte 40 may be filled between the photoelectrode and the counter electrode, thereby producing the dye sensitized solar cell.

The metal oxide nanoparticle paste may be prepared by mixing metal oxide nanoparticles with a solvent to form a colloidal solution with a viscosity of 5×10⁴ to 5×10⁵ cps comprising metal oxide dispersed therein, and adding a binder resin thereto, and then, removing the solvent at 40-70° C. for 30 minutes to 1 hour with a Rotor Evaporator. The metal oxide nanoparticles may be prepared by a hydrothermal synthesis, or prepared using a commercial metal oxide nanoparticle. In addition, the mixing ratio of the metal oxide nanoparticle, binder resin and solvent is not specifically, limited, and for example, metal oxide:Terpineol:ethyl cellulose:lauric acid is 1:2 to 6:0.2 to 0.5:0.05 to 0.3 by weight ratio.

The binder resin is not specifically limited, and any polymer commonly used as a binder may be used. For example, polymers which do not leave organics after heat treatment may be selected. Suitable polymers include polyethylene glycol(PEG), polyethylene oxide(PEO), polyvinyl alcohol(PVA), polyvinylpyrrolidone(PVP), ethyl cellulose, etc. In order to more uniformly disperse the prepared paste, the paste may be dispersed again by introducing it into a 3-roll pulverizer having 3 ceramic rolls rotating like toothed wheels to subject it to a post-treatment.

As the metal oxide nanoparticles, a metal oxide selected from the group consisting of Ti, Zr, Sr, Zn, In, Yr, La, V, Mo, W, Sn, Nb, Mg, Al, Y, Sc, Sm, and Ga, or a mixed oxide thereof may be be used. For example, the metal oxide nanoparticle is selected from the group consisting of titanium oxide(TiO₂), zinc oxide(ZnO), tin oxide(SnO₂) and tungsten oxide(WO₃).

The metal oxide nanoparticles may have the average particle size of 500 nm or less, for example, 1 nm to 100 nm.

The solvent is not specifically limited and those used for preparation of a colloidal solution may be used. For example, ethanol, methanol, terpineol, lauric acid, THF, water, etc. may be used.

The metal oxide nanoparticle paste may be composed of, for examples, titanium oxide, terpineol, ethyl cellulose and lauric acid, or titanium oxide, ethanol and ethyl cellulose.

In addition, the blocking layer 20 may be formed by spin coating metal oxide precursor or nanoparticle solution on a transparent conductive substrate, and then heating in the air or oxygen at high temperature of 450 to 500° C. for 10 minutes or more. The metal oxide nanoparticle layer 32 may be formed by applying the above prepared metal oxide nanoparticle paste on the blocking layer, and then heating in the air or oxygen at 400 to 550° C. for 10 to 120 minutes, for example, at high temperature of 450 to 500° C. for about 30 minutes.

In addition, the counter electrode 70 may be prepared by applying a Platinum (Pt) solution on a transparent conductive substrate, and then heating at high temperature of about 400° C.

As the transparent conductive substrate 10, those commonly used in the art may be used, for example, those obtained by coating a conductive film comprising one selected from indium tin oxide(ITO), fluorine tin oxide(FTO), ZnO—Ga₂O₃, ZnO—Al₂O₃, SnO₂—Sb₂O₃ on a transparent plastic substrate comprising one selected from polyethylenterephthalate(PET), polyethylennaphthalate(PEN), polycarbonate(PC), polypropylene(PP), polyimide(PI), or triacetylcellulose(TAC), or glass substrate may be used.

In order to generate photocharge in the metal oxide nanoparticle layer formed in the photoelectrode, dye materials 31a, 31b may be absorbed.

The first dye material 31a may comprise material capable of absorbing visible rays. IR, and UV rays, and for example, common metal complex, inorganic dye and organic dye can be used. Preferably, as the dye material, Ru complex dye such as N719 (bis(tetrabutylammonium)-cis-(dithiocyanato)-N,N′-bis(4-carboxylato-4′-carboxylic acid-2,2′-bipyridine)ruthenium(II)), or N749 ((4,4′,4″-tricarboxy-2,2′:6′,2′-terpyridine)ruthenium(II)), inorganic dye such as CdSe, organic dye such as TA-St-CA, etc. may be used. For dye absorption, generally used method in dye-sensitized solar cell may be used, and for example, a photoelectrode comprising metal oxide nanoparticles formed therein is immersed in a dispersion comprising dyes, and then dyes are absorbed at appropriate temperature. The solvent for dispersing dyes is not specifically limited, and for example, acetonitrile, dichloromethane or alcohol solvent may be used. After dyes are absorbed, unabsorbed dyes may be washed by solvent washing, etc.

The polymer material 90 may be formed in order to absorb the second dye in the first dye-absorbed metal oxide nanoparticle layer. The kinds of polymer material is not specifically limited, and for examples, polystyrene(PS), polymethyl methacrylate(PMMA), polyvinyl alcohol(PVA), etc. may be used. In order to form a polymer layer, a monomer solution may be induced to liquid oligomer, and the oligomer solution is dispersed in the first dye-absorbed oxide nanoparticle layer and the polymer material is formed in the oxide particle layer using heat or UV, etc. The degree of polymer layer formation may be controlled by changing the degree of polymerization of the oligomer solution and the method of dispersing oligomer in the particle layer.

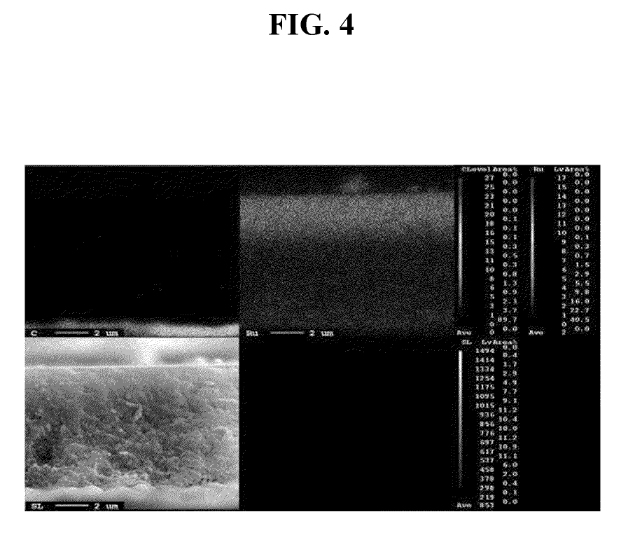

Referring to FIG. 4, where the polymer material forms around nanoparticles comprising the first dye, pore size is rapidly reduced to slow the penetration of the solution. Using this property, desorption of only the top of metal oxide nanoparticle layer may be induced by a basic solution. Then, second dye 31b is reabsorbed in the top layer where first dye is desorbed to form a dual dyes structure. Without a polymer layer, desorption solution and second dye would penetrate into whole oxide particle layer, and a dual dyes structure cannot be formed. Thus, a polymer material is formed in the metal oxide nanoparticle layer for forming a multiple dyes structure. After completing the multiple dyes structure, the polymer material is removed by immersing in an appropriate solvent.

Any basic solution for desorption may be used without limitation if it does not damage a polymer layer. For example, a sodium hydroxide aqueous solution, tetrabutylammonium hydroxide aqueous solution, polymer mixed basic aqueous solution, etc. may be used. The degree of desorption may be controlled by exposure time of desorption solution, kind of desorption material, etc.

In addition, as the second dye material, those having absorption wavelength property identical to or different from the first dye may be used. For example, Ru complex dye such as N719(bis(tetrabutylammonium)-cis-(dithiocyanato)-N,N′-bis(4-carboxylato-4′-carboxylic acid-2,2′-bipyridine)ruthenium(II)), or N749 ((4,4′,4″-tricarboxy-2,2′:6′,2′-terpyridine)ruthenium(II)), inorganic dye such as CdSe, organic dye such as TA-St-CA, etc. may be used. Dye absorption method may be identical to that of the first dye, and in order to control penetration depth of the second dye, absorption time, polymerization degree of oligomer, concentration of dye, molecular size of dye, etc. may be controlled.

The solvent for removing the polymer material includes ethyl acetate, acetone, diethyl ether, etc., but it is not specifically limited thereto, and other solvents may be used that dissolve the corresponding polymer material.

Furthermore, according an exemplary embodiment, third or more dye layers may be additionally formed on the structure comprising first and second dye layers. For this, the processes of polymer material formation, desorption and additional dye reabsorption are repeated one or more time to form multiple dye layers. The degree of absorption of additional dye may be controlled by controlling the depth of desorption of the top layer of the metal oxide nanoparticle layer, and the depth of reabsorption. In addition, the depths of desorption and reabsorption may be controlled by various parameters in the polymer material formation process, desorption process and additional dye reabsorption process. For example, dye layers comprising dyes of wavelengths identical to or different from those of the first and second dyes may be additionally formed by one or more times repeatedly conducting the operation of: after removing the polymer material, reforming polymer material in the second dye layer, desorbing the second dye, reabsorbing additional dye having wavelength different from those of first and second dyes, and removing the polymer material; or, after reabsorbing the second dye, desorbing the second dye, reabsorbing additional dye having wavelength different from those of the first and second dyes, and removing the polymer material. For example, dye material identical to the first and second dyes, i.e., Ru complex dye such as N719 (bis(tetrabutylammonium)-cis-(dithiocyanato)-N,N′-bis(4-carboxylato-4′-carboxylic acid-2,2′-bipyridine)ruthenium(II)), or N749 ((4,4′,4″-tricarboxy-2,2′:6′,2′-terpyridine)ruthenium(II)), inorganic dye such as CdSe, and organic dye such as TA-St-CA, etc. may be used.

Also, according to an exemplary embodiment, a counter electrode comprising at least two kinds of multiple dye layers may be optionally prepared by forming a metal oxide nanoparticle layer on a Pt layer 60 of the counter electrode using a metal oxide paste, and absorbing dyes of different wavelengths.

The method of forming multiple dye layers in the counter electrode may be identical to the method used for the photoelectrode.

According to an exemplary embodiment, the dye-sensitized solar cell comprising the photoabsorption layer 30 having multiple dye layers may be prepared by oppositely arranging the above prepared two electrodes 70, 80 and joining them, and filling electrolyte therebetween.

The electrolyte 40, although shown as one layer in FIG. 2C for convenience, may be practically uniformly dispersed in the porous metal oxide nanoparticle layer 32 between the photoabsorption layers 30.

Since the dye-sensitized solar cell according to an exemplary embodiment is characterized by comprising multiple dye layers in a front electrode 80 and a counter electrode 70, the electrolyte 40 may be of common structure in the art and prepared by commonly used method without limitations.

For example, the electrolyte 40 which is iodide/triodide pair and can receive electrons from the counter electrode 70 and transfer them to dyes of the photo absorption layer 30 by oxidation-reduction may be used.

According to an exemplary method, multiple dyes are layeredly absorbed in a single oxide particle layer of a conductive substrate, thus broadening the range of the photo absorption, and a layered structure is formed in a single oxide particle layer without discontinuous space between the first dye absorbed metal oxide particle layer and additional dye absorbed metal oxide particle layer, thus efficiently manifesting property bands of the two dyes. In addition, removable polymer material is formed in the oxide particle layer to reduce pore size thereof thereby controlling the degree of desorption and reabsorption, thus enabling the formation of a multi-layered structure of the first dye and additional dye. In addition, the multiple dyes layered structure may be formed both in photoelectrode and counter electrode, thus providing a solar cell structure capable of absorbing light in a broader wavelength range.

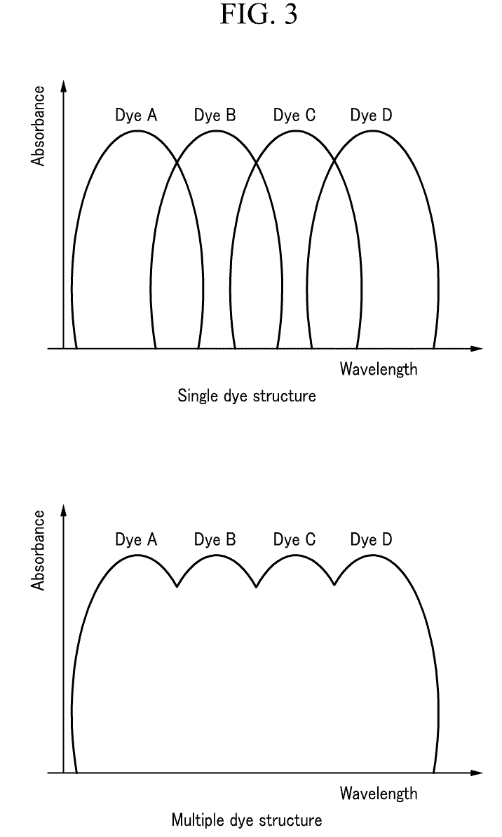

In addition, as shown in FIG. 3, a dye-sensitized solar cell according to an exemplary embodiment, comprising multiple dye layers may broadly absorb solar rays, compared to a known dye-sensitized solar cell comprising a single dye.

Since the dye-sensitized solar cell according to an exemplary embodiment has a layered structure of multiple dyes having different photo absorption wavelengths in a single cell, it can absorb light in a broader wavelength range thereby increasing the photocurrent density and improving the open circuit voltage and fill factor.

The following examples are provided as further illustration and it is understood that embodiments are not limited thereto.

### EXAMPLE 1

(Preparation of a Multi-Wavelength Absorbing Dye-Sensitized Solar Cell with a Multiple-Dyes Layered Structure)

As a substrate for front/rear electrodes, an FTO coated glass substrate was prepared. On the conductive side of a substrate for a rear electrode, H₂PtCl₆ solution was coated, and it was heated at 400° C. for 20 minutes to prepare a counter electrode. For a substrate for a front electrode, the conductive side thereof was masked with an area of 1.5 cm² using an adhesive tape. In addition, it was spin coated with 0.15M titanium(IV) bis(ethyl acetoacetato)diisopropoxide solution, and then, heated at 500° C. for 10 minutes or more to form a blocking layer.

Subsequently, metal oxide nanoparticle paste comprising titanium oxide nanoparticle (average particle size: 20 nm), binder resin(ethyl cellulose) and solvent(Terpineol) was applied to the above two substrates (using doctor blade method), and then, it was heated at 500° C. for 30 minutes to form a metal oxide layer for a front electrode. The thickness of both titanium oxide nanoparticle layers was about 9˜10 μm, and the thickness of the blocking layer was about 30 nm. Subsequently, the front substrate was immersed in an ethanol solution comprising 0.5 mM of Ru type photosensitive dye N719(bis(tetrabutylammonium)-cis-(dithiocyanato)-N,N′-bis(4-carboxylato-4′-carboxylic acid-2,2′-bipyridine)ruthenium(II)) at 50° C. for 1 hour to absorb the photosensitive dye to the particle surface of porous metal oxide layer. Then, a mixed solution of monomers styrene and AIBN (Azobisisobutyronitrile) at a mass ratio of 1:0.01 was preheated at a temperature of boiling point or more to convert it to oligomer, and then, it was spin coated on the above prepared front substrate. The oligomer was polymerized at 70° C. for 20 minutes or more, and then, 0.05 M aqueous solution of tetrabutylammonium was rapidly dropped onto the 45° tilted substrate about 30 times to conduct partial desorption. After desorption was completed, the substrate was immersed in an ethanol solution comprising 0.5 mM of Ru type photosensitive dye N749 ((4,4′,4″-tricarboxy-2,2′:6′,2′-terpyridine)ruthenium(II)) at 50° C. to absorb the photosensitive dye. After dual dye layers were formed, polystyrene layer was removed by immersing in an ethyl acetate solvent.

(Injection of an Electrolyte, Sealing)

The above prepared front electrode and rear electrode were bonded, and then, acetonitrile electrolyte comprising BMI(0.7M) and I2(0.03M) was injected therebetween, and sealed to prepare the multi-wavelength absorbing dye-sensitized solar cell with a dual-dyes layered structure.

### EXAMPLE 2

In order to evaluate the effect of the exemplary multiple dyes layered structure on the improvement of current and efficiency, a dual layered structure consisting of the lower layer N719 and the upper layer N749 was formed in the titanium oxide nanoparticle layer with a thickness of 9˜10 μm according to the process of Example 1.

### COMPARATIVE EXAMPLE 1

In order to compare the effect of the exemplary embodiment with a conventional two-dyes mixed structure (Japanese Patent Laid-open Publication No. 2003-249279), mixed dye of N719 and N749 at a ratio of 1:1 was absorbed to the same titanium oxide nanoparticle layer as Example 2 to prepare an organic dye sensitized solar cell.

### Experiment

For each dye-sensitized solar cell prepared in Example 2 and Comparative Example 1, open circuit voltage, photocurrent density, energy conversion efficiency and fill factor were measured as follows, and the results were summarized in the following Table 1.

[Open Circuit Voltage(V) and Photocurrent Density(mA/cm²)]

:Open circuit voltage and photocurrent density were measured with Keithley SMU2400.

[Energy Conversion Efficiency(%) and Fill Factor(%)]

:Energy conversion efficiency was measured with 1.5 AM 100 mW/cm² solar simulator (consisting of Xe lamp[300W, Oriel], AM1.5 filter, and Keithley SMU2400), and fill factor was calculated using the obtained conversion efficiency and the following Equation.

$$Fill factor ( \% ) = \frac{{( J \times V )}_{max}}{{J}_{sc} \times {V}_{oc}} \times 100 \qquad [ Equation ]$$

wherein J is y-axis value of conversion efficiency curve, V is x-axis value of conversion efficiency curve, and J_{sc} and V_{oc} are intercepts of each axis.

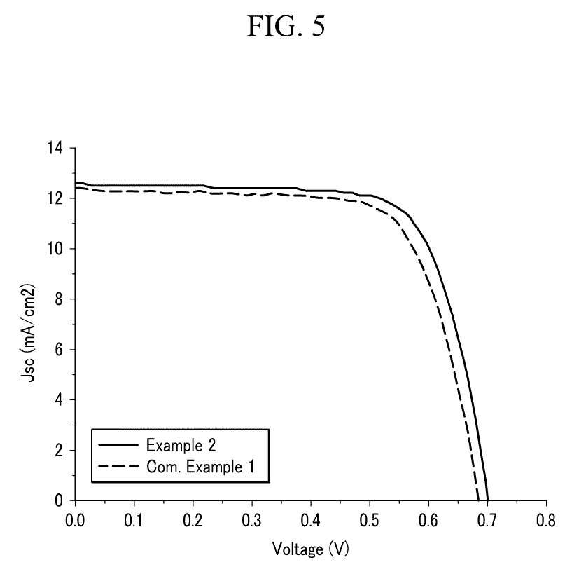

As explained, IPCE (Incident Photon-to-current Conversion Efficiency) of the dye-sensitized solar cells prepared in Example 2 and Comparative Example 1 was measured. FIG. 5 shows the results of measuring the current-voltage under 1.5 AM light irradiation.

TABLE 1

| | Photocurrent | Open circuit | Fill factor | efficiency |
|---|---|---|---|---|
| | density (mA/cm²) | voltage (mV) | (%) | (%) |
| Example 2 | 12.6 | 701.7 | 72.1 | 6.4 |
| Comparative | 12.4 | 685.9 | 70.9 | 6.0 |
| Example 1 | | | | |

As shown in Table 1 and FIG. 5, the dye-sensitized solar cell with dual-dyes layered structure (Example 2) manifests higher performances in terms of current density, open circuit voltage and fill factor, compared to the solar cell manufactured using mixed dye of N719 and N749 with a ratio of 1:1, and, it shows efficiency of 6.4% which is 6.7% increased value compared to the Comparative Example 1.

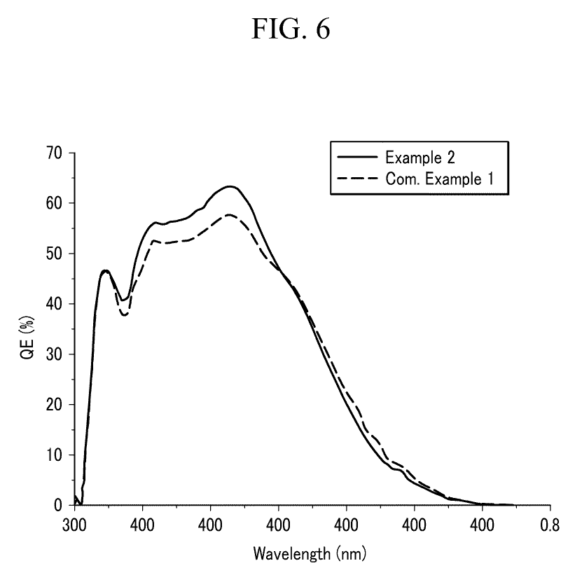

Also, IPCE (Incident Photon-to-current Conversion Efficiency) is shown in FIG. 6. As shown in FIG. 6, the dye-sensitized solar cell comprising N749 and N719 in a dual-dyes layered structure manifests a broad light absorbing property similarly to the solar cell of the Comparative Example 1 which is made of a mixed solution of two kinds of dyes N719/N749 with a ratio of 1:1, but the dual-dyes layered structure manifests N719 dye property better. This is because in the structure of the Comparative Example 1, N719 dye shares space in the nanoparticle layer with N749 dye; thus substantial area of N719 in the whole nanoparticle layer area decreases. Therefore, in the dual-dyes layered structure according to an exemplary embodiment, N719 absorption layer which is adjacent to light incident plane sufficiently absorbs light in a short wavelength range, and continuously stacked N749 layer absorbs a longer wavelength penetrated thereafter, thereby showing improved solar cell performances. In addition, since the lower layer exists as pure N719 dye instead of mixed type, open circuit voltage and fill factor are also improved. Practically, as changed by surface integral in FIG. 5, current density was 10.7 for Example 2 and 10.3 for the Comparative Example 1; showing 3.9% increase in current density.

Accordingly, in the dual-dyes layered structure according to an exemplary embodiment, currents generated by N719 and N749 are efficiently transferred through the oxide particle layer, and such a structure can utilize a broader light than simple mixing of two dyes and show improved results in terms of basic cell performances.

The teachings herein may be applied to manufacture of a multi-wavelength absorbing dye-sensitized solar cell capable of absorbing solar rays broadly.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A dye-sensitized solar cell comprising:
a photoelectrode comprising at least two kinds of dye layers having different wavelengths on a transparent conductive substrate;
a counter electrode comprising a platinum (Pt) layer on a transparent conductive substrate, arranged opposite to the photoelectrode; and
an electrolyte filled between the photoelectrode and the counter electrode.

2. The dye-sensitized solar cell according to claim 1, wherein the dye layer comprises identical or different kinds of dyes.

3. The dye-sensitized solar cell according to claim 1, wherein the dye layer comprises dyes selected from the group consisting of metal complex, inorganic dye and organic dye.

4. The dye-sensitized solar cell according to claim 1, wherein the dye layer comprises a metal oxide nanoparticle layer to which dyes are absorbed.

5. The dye-sensitized solar cell according to claim 4, wherein the metal oxide nanoparticle layer comprises at least one selected from the group consisting of titanium oxide, zirconium oxide, strontium oxide, zinc oxide, indium oxide, lanthanum oxide, vanadium oxide, molybdenum oxide, tungsten oxide, tin oxide, niobium oxide, magnesium oxide, aluminum oxide, yttrium oxide, scandium oxide, samarium oxide, gallium oxide, and strontium titanium oxide.

6. The dye-sensitized solar cell according to claim 1, further comprising at least two kinds of dye layers having different wavelengths on the platinum (Pt) layer of the counter electrode.

7. The dye-sensitized solar cell according to claim 6, wherein the dye layer comprises identical or different kinds of dyes.

8. The dye-sensitized solar cell according to claim 6, wherein the dye layer comprises dyes selected from the group consisting of metal complex, inorganic dye and organic dye.

9. The dye-sensitized solar cell according to claim 6, wherein the dye layer comprises a metal oxide nanoparticle layer to which dyes are absorbed.

10. The dye-sensitized solar cell according to claim 9, wherein the metal oxide nanoparticle layer comprises at least one selected from the group consisting of titanium oxide, zirconium oxide, strontium oxide, zinc oxide, indium oxide, lanthanum oxide, vanadium oxide, molybdenum oxide, tungsten oxide, tin oxide, niobium oxide, magnesium oxide, aluminum oxide, yttrium oxide, scandium oxide, samarium oxide, gallium oxide, and strontium titanium oxide.

11. A method for preparing a dye-sensitized solar cell, the method comprising:
forming a metal oxide nanoparticle layer on a transparent conductive substrate having a blocking layer formed thereon, and absorbing a first dye to the metal oxide nanoparticle layer;
forming a polymer material in the metal oxide nanoparticle layer to which the first dye is absorbed;
desorbing dyes on top of the substrate having the polymer material formed thereon using a basic desorption solution;
reabsorbing a second dye on the desorbed part;
removing the polymer material after absorption of the second dye to prepare a photoelectrode having at least two kinds of dye layers having different wavelengths;
forming a platinum (Pt) layer on a transparent conductive substrate to prepare a counter electrode; and
oppositely arranging the photoelectrode and the counter electrode, and filling an electrolyte therebetween.

12. The method according to claim 11, wherein additional dye layers are formed by one or more times conducting:
after removing the polymer material, reforming a polymer material in the second dye layer, desorbing the second dye, reabsorbing an additional dye having a wavelength different from those of the first and second dyes, and removing the polymer material; or
after reabsorbing the second dye, desorbing the second dye, reabsorbing the additional dye having the wavelength different from those of the first and second dyes, and removing the polymer material.

13. The method according to claim 11, wherein the polymer material is formed by dispersing an oligomer material in the oxide particle layer, and forming the polymer material in the particle layer by polymerization.

14. The method according to claim 11, wherein the blocking layer is formed by spin coating metal oxide precursor or metal oxide nanoparticle solution on a transparent conductive substrate, and the metal oxide nanoparticle layer is formed by applying metal oxide paste on the blocking layer and heating.

15. The method according to claim 14, wherein the heating is conducted at a temperature of from 400 to 550° C. for 10 to 120 minutes.

16. The method according to claim 11, wherein the method further comprises:
applying a nanoparticle paste on the platinum (Pt) layer of the counter electrode and heating it to form a metal oxide nanoparticle layer;
absorbing the first dye into the metal oxide nanoparticle layer;
forming the polymer material in the metal oxide nanoparticle layer to which the first dye is absorbed;
desorbing dyes on top of the substrate having the polymer material formed thereon using a basic desorption solution;
reabsorbing the second dye on the desorbed part; and
removing the polymer material after absorption of the second dye to prepare a counter electrode comprising at least two kinds of dye layers having different wavelengths.

17. The method according to claim 16, wherein additional dye layers are formed by one or more times conducting:
after removing the polymer material, reforming a polymer material in the second dye layer, desorbing the second dye, reabsorbing an additional dye having a wavelength different from those of the first and second dyes, and removing the polymer material; or
after reabsorbing the second dye, desorbing the second dye, reabsorbing the additional dye having the wavelength different from those of the first and second dyes, and removing the polymer material.

18. The method according to claim 16, wherein the heating is conducted at a temperature of from 400 to 550° C. for 10 to 120 minutes.

19. The method according to claim 16, wherein the polymer material is formed by dispersing an oligomer material in the oxide particle layer, and forming the polymer material in the particle layer by polymerization.
